(19) United States
(12) Patent Application Publication
(10) Pub. No.: US 2025/0044711 A1
(43) Pub. Date: Feb. 6, 2025

(54) TEMPERATURE-INSENSITIVE ACTUATOR AND DEFORMATION MIRROR

(71) Applicant: Carl Zeiss SMT GmbH, Oberkochen (DE)

(72) Inventors: Andreas Raba, Niederschoenenfeld (DE); Markus Hauf, Ulm (DE)

(21) Appl. No.: 18/921,052

(22) Filed: Oct. 21, 2024

Related U.S. Application Data
(63) Continuation of application No. PCT/EP2023/059167, filed on Apr. 6, 2023.

(30) Foreign Application Priority Data
Apr. 26, 2022 (DE) 10 2022 204 014.7

(51) Int. Cl. G03F 7/00

(52) U.S. Cl. CPC G03F 7/7095; G03F 7/70141; G03F 7/70266; G03F 7/70833

(57) ABSTRACT

An actuator for semiconductor lithography comprises an actuator element, a compensation element and a connection element. The actuator element has a first coefficient of thermal expansion and a connection site at its first end for the active adjustment of an optical element along at least one adjustment axis. The compensation element has a second coefficient of thermal expansion. The sign of the second coefficient of thermal expansion corresponds to the sign of the first coefficient of thermal expansion. The compensation element is oriented coaxially in relation to the adjustment axis. The compensation element has a coupling site held stationary in space or stationary in relation to the optical element. The connection element connects the actuator element and the compensation element at positions located remote from the connection site and from the coupling site. A deformation mirror includes a mirror substrate and an actuator.

### CROSS-REFERENCE TO RELATED APPLICATIONS

The present application is a continuation of, and claims benefit under 35 USC 120 to, international application No. PCT/EP2023/059167, filed Apr. 6, 2023, which claims benefit under 35 USC 119 of German Application No. 10 2022 204 014.7, filed Apr. 26, 2022. The entire disclosure of each of these applications is incorporated by reference herein.

### FIELD

The disclosure relates to an actuator, such as a solid-state actuator, for semiconductor lithography, comprising an actuator element having a first coefficient of thermal expansion and a connection site at its first end for the active adjustment of an optical element along and/or parallel to at least one adjustment axis.

### BACKGROUND

Projection exposure apparatuses are used for producing extremely fine structures, such as on semiconductor components or other microstructured component parts. The apparatuses produce extremely fine structures down to the nanometer range by way of generally reducing imaging of structures on a mask, a so-called reticle, on an element to be structured, a so-called wafer, that is provided with photosensitive material. The minimum dimensions of the structures produced are directly dependent on the wavelength of the light used. The light is shaped for the optimum illumination of the reticle in an illumination optical unit. Recently, light sources having an emission wavelength in the range of a few nanometers, for example between 1 nm and 120 nm, such as in the region of 13.5 nm, have increasingly been used. The described wavelength range is also referred to as the EUV range.

Apart from with the use of systems which operate in the EUV range, the microstructured component parts are also produced using commercially established DUV systems, which have a wavelength of between 100 nm and 300 nm, for example 193 nm. With the desire to be able to produce smaller and smaller structures, the optical correction properties in the systems have likewise increased further. There is an increase in the throughput of each new generation of projection exposure apparatuses in the EUV range or DUV range so as to increase the profitability; this typically leads to a greater thermal load and hence to more imaging aberrations caused by the heat.

To correct the imaging aberrations, in the individual or all optical assemblies of the projection optical unit, use can be made of so-called manipulators, inter alia, which alter the position and alignment of the optical elements or else influence the imaging properties of the optical elements, for example mirrors, by deforming the optical effective surface. In this case, an optical effective surface is understood to mean that surface of an optical element which is impinged on by used light during the operation of the assigned apparatus. In this case, used light should be understood to mean electromagnetic radiation which is used for imaging the structures.

In order to be able to adjust, i.e. manipulate, an optical element, use is usually made of actuators, such as solid-state actuators. In this case, a thermal expansion that occurs as a result of the increasing thermal load can result in a disturbance of the positioning. In conjunction with deformable optical units, imaging aberrations can be a consequence.

DE 10 2020 201 774 A1 is concerned with the thermal expansion of solid-state actuators, which is compensated for via CTE matching (CTE: coefficient of thermal expansion), i.e. compensation of the thermal expansion coefficients. In that case, the actuator comprises different materials having different coefficients of thermal expansion, and so the composite thus formed results in a desired expansion behaviour. Many materials which exhibit an electro-, piezo-, magneto- or photostrictive behaviour and can be suitable for use as a solid-state actuator have a positive coefficient of thermal expansion, that is to say that the body expands as the temperature rises. In order to be able to compensate for the thermal expansion behaviour, a combination with a material having a negative CTE can thus be desirable. Materials having negative CTEs are, in general, suitable only to a limited extent for use in projection exposure apparatuses, since they tend towards degradation under the prevailing ambient conditions. Other materials such as zirconium tungstate can give rise to other design and process engineering difficulties.

Furthermore, it is known to use athermal lens element mounts, in which a first mount element is connected to the lens element at one end and to a compensation element arranged parallel to the first mount element at the other end.

### SUMMARY

The present disclosure seeks to provide an actuator and a deformation mirror which eliminate or at least reduce at least some undesirable features.

In an aspect, the disclosure provides an actuator for semiconductor lithography. The actuator comprises an actuator element having a first coefficient of thermal expansion and a connection site at its first end for the active adjustment of an optical element along at least one adjustment axis. The actuator also comprises a compensation element, which has a second coefficient of thermal expansion, the sign of which corresponds to that of the first coefficient of thermal expansion, which is oriented coaxially in relation to the adjustment axis and which has a coupling site held stationary in space or stationary with respect to the optical element. The actuator further comprises a connection element, by which the actuator element and the compensation element are connected at positions located remote from the connection site and from the coupling site.

In an aspect, the disclosure provides a deformation mirror for a lithography arrangement, which comprises a mirror substrate having a reflective surface and a mirror rear side situated opposite the reflective surface. The deformation mirror also comprises at least one actuator according to the disclosure. The actuator element of the actuator is connected to the mirror rear side.

A compensation element has a second coefficient of thermal expansion, the sign of which corresponds to that of the first coefficient of thermal expansion, and the compensation element is oriented coaxially, for example parallel, in relation to the adjustment axis and has a coupling site held stationary in space or stationary with respect to the optical element. The optical element can be a mirror or a lens element, for example, where the mirror or the lens element can also comprise a frame-such as a force frame. In the present case, the expression stationary with respect to the optical element is thus understood to mean that the coupling site is held either stationary with respect to the mirror body and/or the mirror rear side or stationary with respect to the lens element body and/or lens element edge or stationary with respect to the frame or stationary with respect to a linking site of the optical element, at which the coupling site is connected to the optical element, or else with respect to any other reference element assigned to the optical element. Furthermore, a connection element is present, by which the actuator element and the compensation element are connected at positions located remote from the connection site and from the coupling site.

The compensation element having a second coefficient of thermal expansion, the sign of which corresponds to that of the first coefficient of thermal expansion, can make it possible to compensate for an expansion of the actuator element caused by temperature change via an equidirectional extension of the compensation element. In this connection, a thermal expansion should be understood to mean that the geometry of an element as a whole changes in the event of a change in temperature, i.e. for example the length of the element increases or decreases. The thermal expansion of an element should thus be understood to be analogous to the coefficient of thermal expansion of a material.

On account of the coupling site, which is held either stationary in space or stationary with respect to the optical element or a reference element assigned thereto, such as a frame, that is to say is fixedly connected to the optical element, the connection site of the actuator element can be adjustable relative to the coupling site. In this case, the position of the connection element in space is defined by the compensation element. If the compensation element undergoes greater expansion than the actuator element, then the connection site of the actuator element will be displaced relative to the coupling site in a first (negative) direction along or parallel to the adjustment axis. Conversely, if the thermal expansion of the compensation element is less than that of the actuator element, then the connection site will be displaced relative to the coupling site in a second (positive) direction along or parallel to the adjustment axis, the second direction being opposite to the first direction. The choice of the geometry and/or the material and/or the coefficient of thermal expansion and/or the configuration of the linking between the actuator element and the optical element allows the temperature-dependent adjustment of the connection site to be influenced, in such a way that the adjustment of the connection site takes place independently of temperature. In this case, the term “adjustment” of the optical element encompasses a translational and/or rotational movement or else displacement of the (entire) optical element that is caused by the actuator, and also an at least regional deformation of the optical element that is caused by the actuator.

In this case, the actuator element can have an electro-, piezo-, magneto- or photostrictive behaviour. In general, other kinds of actuator are also conceivable which are suitable for an application in semiconductor technology, such as in projection exposure apparatuses for semiconductor technology. For example, the actuator element can be formed as a piezoactuator element. In this case, the actuator can have a layered construction. Analogously, the compensation element can also be formed in multilayered fashion. This can make it possible to combine different materials in one compensation element. The actuator can have any desired shape in this case. It can be configured as parallelepipedal, cylindrical or prismatic, such as with a polygonal, for example hexagonal or octagonal, base surface. Furthermore, the actuator element can be embodied and controllable in such a way that it is adjustable monodirectionally or bidirectionally in relation to the adjustment axis.

In the context of the disclosure, the actuator element and the compensation element can be connected to one another terminally, such as at the end faces, using the connection element; however, it is alternatively also possible for the actuator element and the compensation element to be connected to one another at any desired site; consequently, there is one or a plurality of local connections. For example the actuator element and the compensation element can be connected to one another cohesively or in a force-locking manner. This connection can be effected via direct joining, cohesive joining, that is to say adhesive bonding, welding, soldering, or pressing.

Furthermore, for example during the use of an actuator in a projection exposure apparatus under the ambient conditions prevailing there, the first coefficient of thermal expansion and the second coefficient of thermal expansion can both positive, although it is also possible for the first coefficient of thermal expansion and the second coefficient of thermal expansion to be both negative.

Furthermore, the coefficients of thermal expansion of the actuator element and of the compensation element can match one another. For example, the actuator element and the compensation element can be manufactured from the same substance, i.e. the same material, for example from the same semifinished product. The actuator element and the compensation element can have matching extents along or parallel to the adjustment axis. With matching coefficients of thermal expansion and a matching extent along or parallel to the adjustment axis of actuator element and compensation element—assuming an at least approximately homogeneous temperature distribution within the actuator—a complete compensation of the compression or expansion of the actuator caused by temperature change is possible, such that the actuator is temperature-insensitive or else athermal.

However, depending on the configuration of the actuator and the linking thereof to the optical element, the extent along the adjustment axis and/or the coefficients of thermal expansion of actuator element and compensation element can also be different, for example differ from one another by a factor. If there is a prevailing temperature gradient between the coupling site and the connection site in the actuator, it can be if the coefficients of thermal expansion and/or the extents of the actuator element and of the compensation element along or parallel to the adjustment axis differ from one another. In this case, given a known temperature within a heat conducting path within the actuator and given knowledge of the thermal resistances in the compensation element and in the actuator element, the extent along or parallel to the adjustment axis and the coefficient of thermal expansion can be adapted in such a way that a heat-flow-induced displacement can be compensated for. In other words, it is possible to find a pair consisting of coefficient of thermal expansion and extent for the compensation element and the actuator element, such that a heat-flow-induced displacement is reduced or compensated for. As an additional parameter, the thermal conductivity of the actuator element and/or of the compensation element can be adapted.

Furthermore, the compensation element can be formed as a further actuator element. In this case, the actuator element and the further actuator element can be bidirectionally or monodirectionally adjustable along or parallel to the adjustment axis. Furthermore, one out of the actuator element and the further actuator element can be used exclusively for an adjustment of the optical element in a first direction along or parallel to the adjustment axis, while the other out of the actuator element and the further actuator element is used exclusively for an adjustment of the optical element in a direction along or parallel to the adjustment axis, the direction being opposite to the first direction. This can help minimize the hysteresis in the case of piezoactuators, such as in the case of ceramic piezoactuators, but also in the case of crystalline piezoactuators. Moreover, it is desirable if one out of the actuator element and the further actuator element, such as the control of the respective actuator elements, is configured (exclusively) to compress and the other out of the actuator element and the further actuator element is configured (exclusively) to expand. A doubling of the total travel of the actuator is made possible by the resultant superposition of the individual travels. It goes without saying that both, i.e. the further actuator element and the actuator element, can also be configured (exclusively) to compress or (exclusively) to expand.

In order to minimize the temperature differences of actuator element and compensation element, both can be in good thermal contact with one another. Therefore, if the actuator element and the compensation element can be connected to one another at least in portions in a gap formed between them. In other words, the actuator can have an additional (second) connection. In this case, the connection can be formed via a flexure or a heat conducting element or else via a ductile solid.

In an embodiment, the gap is at least partly filled with a liquid having a higher thermal conductivity than the thermal conductivity of air. Thermally conductive pastes, oils, such as transformer oils, are suitable for this purpose.

In order to ensure a better linking to the optical element to be adjusted, the actuator element can be formed in bipartite fashion, only one part of which is formed from an actively controllable, i.e. piezoelectric, electrostrictive, piezoelectric or magnetostrictive, material. In order to increase the thermal resistance between the optical element and the actuator, a constriction can be embodied at the other part. Alternatively or supplementarily, it is also possible for the other part, i.e. the actively controllable part of the actuator element, to have an increased heat transfer resistance in comparison with the afore the one part. Analogously thereto, the compensation element can also be embodied in bipartite fashion, comprising (or consisting of) a compensating element and a second part/adapter for connection to the optical element or the frame of the optical element. The linking to the optical element can be effected for example cohesively by way of adhesive bonding/joining. Alternatively, the other part can also be a constituent part of the optical element. The other part can be formed from the same substance as the optical element. However, the other part can be monolithically connected to the optical element or ground from a glass block.

In order to simplify the design of the actuator, one out of the actuator element and the compensation element can be formed as a hollow body, and the other out of the actuator element and the compensation element can be accommodated in the hollow body. Either the actuator element or the compensation element can be formed as a hollow body, in which the other element is accommodated. In this case, the hollow body can be formed as a hollow cylinder, or else a hollow parallelepiped or a hollow prism. The element formed as a hollow body then can have two or more connection sites to the optical element, or respectively coupling sites.

Furthermore, a plurality of compensation elements can also be present, which compensation elements are connected to the actuator element. These can be arranged at a distance from one another, for example at a regular distance from one another, around the actuator element at the outer periphery. If the compensation elements are formed as further actuator elements, then a failure, for example an electrical failure, of one of the compensation elements can be compensated for by one of the others.

The deformation mirror according to the disclosure for semiconductor lithography comprising a mirror substrate having a reflective surface and a mirror rear side situated opposite the reflective surface is determined by the fact that at least one actuator described above is present, the actuator element of which is connected to the mirror rear side. Deflection of the actuator deforms the mirror rear side and the mirror substrate at least in portions, as a result of which, by virtue of the stiffness of the mirror, the optically active surface, i.e. the reflective surface, of the mirror is also deformed at least in portions. As a result of the deformation of the optically active mirror surface, the imaging properties of the mirror are changed, with the result that imaging aberrations of the projection optical unit can be compensated for. An optically active surface is understood here to be a surface which, during normal operation of the associated apparatus, is impinged on by used radiation, i.e. radiation used for imaging and exposure. By virtue of the specific configuration of the actuator, an adjustment of the actuator can take place more independently of temperature and thus more accurately since an adjustment/change in length of the actuator element along or parallel to the adjustment axis that is triggered by a change in temperature is compensated for by an equidirectional movement of the compensation element.

In this case, the embodiments and features mentioned in connection with the actuator are also applicable to the deformation mirror having at least one actuator.

In one embodiment, the deformation mirror can have a force frame, i.e. a frame is arranged between the actuator and the mirror rear side. The compensation element, at the coupling site, can be indirectly or directly connected to a frame rear side facing away from the mirror rear side. The frame additionally can have at least one passage in which the actuator element and/or the adapter are/is arranged. The frame can have a plurality of passages, for example a number of passages adapted to the number of actuator elements.

Alternatively, the at least one compensation element, at the coupling site, is also directly or indirectly (via an adapter) connected to the mirror rear side. This makes possible a so-called force-frame-free, i.e. frame-free, embodiment. The compensation element and the actuator element can bee linked to the same heat source, namely the mirror rear side. If the mirror temperature increases on account of the incidence of light, then the same heat input on the actuator and the compensation element can be expected. Moreover, the manufacture of the deformation mirror can be simplified.

Further features, properties and aspects of the present disclosure are described in more detail below on the basis of embodiment variants and with reference to the appended figures. In this respect, all the features described above and below can be used both individually and in any desired combination. The embodiment variants described below are merely examples which, however, do not limit the subject matter of the disclosure.

### BRIEF DESCRIPTION OF THE DRAWINGS

In the figures here:

FIG. 1A shows a schematic illustration of a microlithographic projection exposure apparatus designed for operation in the EUV;

FIG. 1B shows a schematic illustration of a microlithographic projection exposure apparatus designed for operation in the DUV;

FIG. 2 shows a schematic sectional illustration of a first exemplary embodiment of the actuator according to the disclosure;

FIG. 3 shows a schematic sectional illustration of a second exemplary embodiment of the actuator according to the disclosure;

FIG. 4 shows a schematic sectional illustration of a third exemplary embodiment of the actuator, in which the compensation element is embodied as a further actuator element;

FIG. 5 shows a schematic illustration of a fourth exemplary embodiment comprising three compensation elements;

FIG. 6 shows a schematic sectional illustration of the actuator according to FIG. 4 in conjunction with an optical element;

FIG. 7 shows a schematic sectional illustration of the actuator element;

FIG. 8 shows a schematic illustration of a deformation mirror comprising a plurality of actuators with a force frame; and

FIG. 9 shows a schematic illustration of a deformation mirror comprising a plurality of actuators without a force frame.

### DETAILED DESCRIPTION

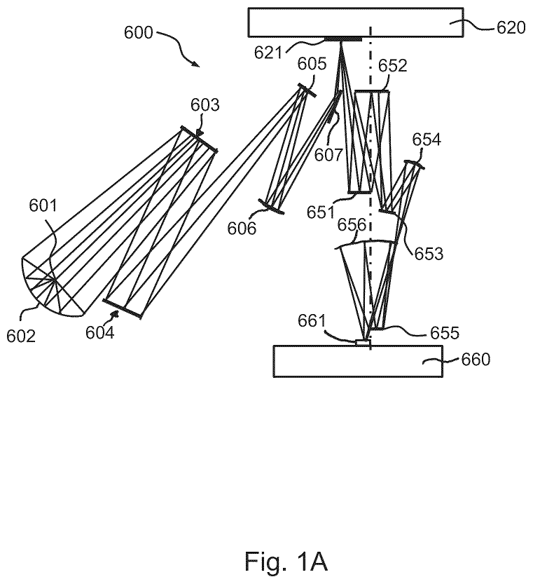

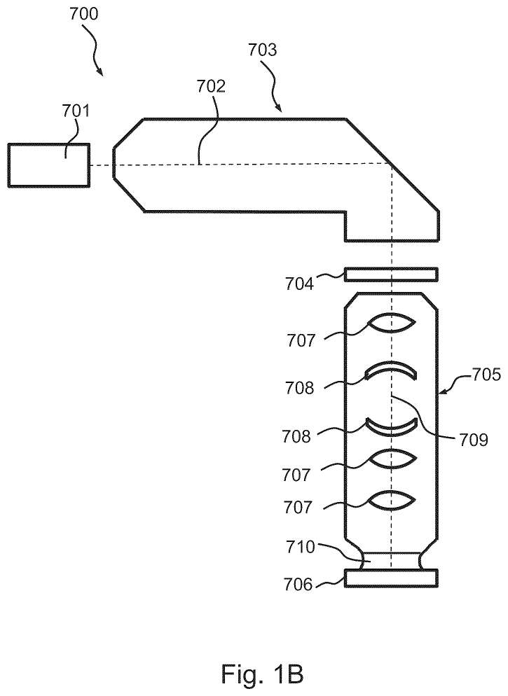

FIG. 1A shows a schematic illustration of an exemplary projection exposure apparatus 600 designed for operation in the EUV, in which the present disclosure is implementable, that is to say in which the actuator 100 according to the disclosure can be used. However, the disclosure can also be used in other nanopositioning systems.

In accordance with FIG. 1A, an illumination device in a projection exposure apparatus 600 designed for EUV comprises a field facet mirror 603 and a pupil facet mirror 604. The light from a light source unit comprising a plasma light source 601 and a collector mirror 602 is directed at the field facet mirror 603. A first telescope mirror 605 and a second telescope mirror 606 are arranged downstream of the pupil facet mirror 604 in the light path. Arranged downstream in the light path is a deflection mirror 607, which directs the radiation incident on it at an object field in the object plane of a projection lens comprising six mirrors 651-656. At the location of the object field, a reflective structure-bearing mask 621 is arranged on a mask stage 620 and with the aid of the projection lens is imaged into an image plane, in which a substrate 661 coated with a light-sensitive layer (photoresist) is situated on a wafer stage 660.

The disclosure can likewise be used in a DUV apparatus, as illustrated in FIG. 1B. A DUV apparatus is set up in general like the above-described EUV apparatus from FIG. 1A, wherein mirrors and lens elements can be used as optical elements in a DUV apparatus and the light source of a DUV apparatus emits used radiation in a wavelength range of 100 nm to 300 nm.

The DUV lithography apparatus 700 illustrated in FIG. 1B has a DUV light source 701. By way of example, an ArF excimer laser that emits radiation 702 in the DUV range at 193 nm, for example, can be provided as the DUV light source 701. A beam shaping and illumination system 703 guides the DUV radiation 702 onto a photomask 704. The photomask 704 is embodied as a transmissive optical element and can be arranged outside the systems 703. The photomask 704 has a structure which is imaged onto a wafer 706 or the like in a reduced fashion via the projection system 705. The projection system 705 has a plurality of lens elements 707 and/or mirrors 708 for imaging the photomask 704 onto the wafer 706. In this case, individual lens elements 707 and/or mirrors 708 of the projection system 705 can be arranged symmetrically with respect to the optical axis 709 of the projection system 705. It should be noted that the number of lens elements 707 and mirrors 708 of the DUV lithography apparatus 700 is not restricted to the number illustrated. A greater or lesser number of lens elements 707 and/or mirrors 708 can also be provided. For example, the beam shaping and illumination system 703 of the DUV lithography apparatus 700 comprises a plurality of lens elements 707 and/or mirrors 708. Furthermore, the mirrors are generally curved on their front side for beam shaping purposes. An air gap 710 between the last lens element 707 and the wafer 706 can be replaced by a liquid medium having a refractive index of >1. The liquid medium can be high-purity water, for example. Such a set-up is also referred to as immersion lithography and has an increased photolithographic resolution. The actuators according to the disclosure can be used for the adjustment of the lens elements 707 and or mirrors 708 and/or for the deformation thereof in the DUV lithography apparatus 700, such as in the projection system 705 thereof.

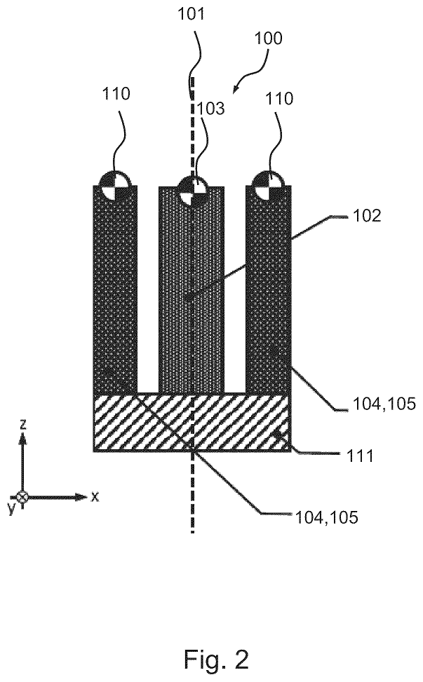

FIG. 2 shows a first exemplary embodiment of the actuator 100 for semiconductor lithography according to the disclosure. This actuator has an actuator element 102 having a first coefficient of thermal expansion and a connection site 103 at its first end for the active adjustment of an optical element 300 (not illustrated more specifically)—for example a lens element or a mirror—along or parallel to at least one adjustment axis 101 (the z-axis in the present case). Moreover, a compensation element 104 is present, which has a second coefficient of thermal expansion, the sign of which corresponds to that of the first coefficient of thermal expansion. The compensation element 104 and the actuator element 102 can thus both have a positive coefficient of thermal expansion or a negative coefficient of thermal expansion. The compensation element 104 is oriented coaxially, for example parallel, in relation to the adjustment axis 101. Moreover, the compensation element 104 has at least one coupling site 110 held stationary in space or stationary with respect to the optical element 300, or a reference element assigned to the optical element 300, such as a frame 200, for example. That is to say that the connection site 103 is movable relative to the coupling site 110. The actuator element 102 and the compensation element 104 are connected by a connection element 111 at a position located remote from the connection site 103 and from the coupling site 110. In this case, the actuator element 102 can be formed from a substance which exhibits an actively controllable, such as an electrostrictive, piezostrictive, magnetostrictive or photostrictive, behaviour. The actuator element 102 can be formed as a piezoactuator element. In this case, the piezoactuator element can have a plurality of piezostrictive layers that are stacked one above another. The use of relaxor ferroelectrics such as lead magnesium niobate (PMN) likewise represents a possibility. If the actuators 100 are formed as piezoelectric actuators 100, then these can be formed as crystalline piezoactuators, for example based on niobates, such as lithium niobate.

In the present case here the actuator 100 shown in FIG. 2 has an adjustment axis 101 in the z-direction, and so an optical element 300 (not illustrated more specifically), such as a mirror or a lens element, can be adjusted along or parallel to the z-axis. In this case, the actuator 100 is distinguished by the fact that the distance between the connection site 103 and the coupling site 110 along or parallel to the adjustment axis 101 is independent of temperature. If the thermal expansion of the compensation element 104 is greater than the thermal expansion of the actuator element 102, then the connection site 103 will be displaced relative to the coupling site 110 in the negative z-direction. By contrast, if the thermal expansion of the compensation element 104 is less than that of the actuator element 102, then the connection site 103 will be displaced relative to the coupling site 110 in the positive z-direction in FIG. 2. Suitable choice of the geometry, such as of the length, and of the coefficients of thermal expansion, of the material and also of the connection between the optical element 300 and the actuator 100 makes it possible to realize an athermal design of the actuator 100, that is to say a temperature-independent adjustment along, for example parallel to, the adjustment axis 101.

In this case, the position of the connection element 111 is defined by the extent of the compensation element 104 along or parallel to the adjustment axis 101. In the simple case, with a homogeneous temperature distribution within the actuator 100, and if the coefficients of thermal expansion of the compensation element 104 and of the actuator element 102 match one another, and the extents/lengths along or parallel to the adjustment axis 101 match one another, a temperature-induced thermal expansion of the compensation element 104 thus results in a displacement of the connection element 111 along the negative z-axis. Under the assumptions made above, the absolute value of the thermal expansion of the actuator element 102 matches that of the compensation element 104, that is to say that a temperature-induced displacement of the connection site 103 of the actuator element 102 in the positive z-direction would thus be compensated for by a displacement of the connection element 111, induced by the compensation element 104, by the same absolute value in the negative z-direction.

FIG. 2 additionally shows that, in the present case, the compensation element 104 is connected to the actuator element 102 terminally via the connection element 111. This connection can be effected via direct joining, cohesive joining, such as adhesive bonding, welding, soldering, or via force locking engagement such as pressing.

The extents of the actuator element 102 and of the compensation element 104 along or parallel to the adjustment axis 101 additionally match in the present case. Moreover, the compensation element 104 is formed as a hollow cylinder, in which the actuator element 102 is accommodated.

However, the coefficients of thermal expansion and the extents along or parallel to the adjustment axis 101 of compensation element 104 and actuator element 102 can also differ from one another, such as by a factor.

In an alternative embodiment (not illustrated more specifically), for example, if there is a prevailing temperature gradient between the coupling site 110 and the connection site 103 in the actuator 100, the coefficients of thermal expansion and/or the extents of the actuator element 102 and of the compensation element 104 along or parallel to the adjustment axis 101 can differ from one another. In this case, given a known temperature within a heat conducting path within the actuator 100 and given knowledge of the thermal resistances in the compensation element 104 and in the actuator element 102, the extent along or parallel to the adjustment axis 101 and the coefficient of thermal expansion can be adapted in such a way that a heat-flow-induced displacement/change in length can be reduced or compensated for. In other words, it is possible to find a pair consisting of coefficient of thermal expansion and extent for the compensation element 104 and the actuator element 102, such that a heat-flow-induced displacement/change in length is reduced or compensated for. The thermal conductivity of the actuator element 102 and/or of the compensation element 104 and/or of the connection element 111 can be adapted as a further parameter.

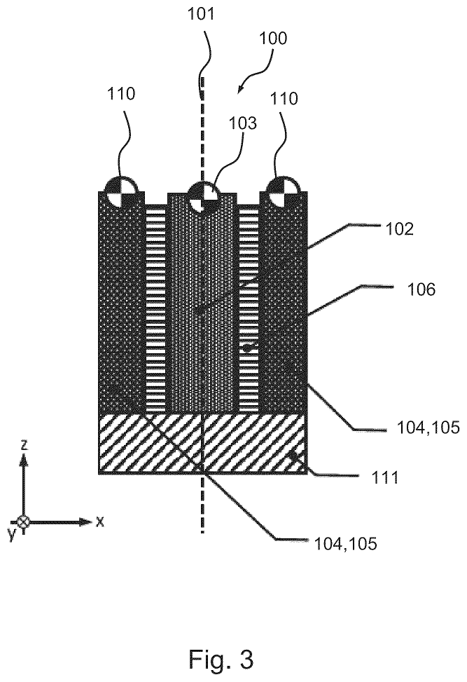

FIG. 3 shows a further exemplary embodiment of the actuator 100 according to the disclosure, in which a gap 106 embodied between the actuator element 102 and the compensation element 104 thermally connects the elements to one another at least in portions, that is to say that the elements are in thermal contact with one another. This improves the thermal conductivity and makes it possible to minimize temperature differences between the elements 102, 104. The connection in portions can be effected by the incorporation of thermal bridges, for example (flexible) flexures, heat conducting elements, or by the gap 106 being filled via a liquid having a higher thermal conductivity than the thermal conductivity of air. By way of example, thermally conductive pastes and oils, such as transformer oils, are suitable here as well. Likewise, the gap 106 can be wholly or partly filled with an elastic material such as metal, solder or plastic. The plastic can be embodied as an elastic composition and can be admixed with metallic and/or ceramic elements such as particles and/or fibres in order to increase the thermal conductivity.

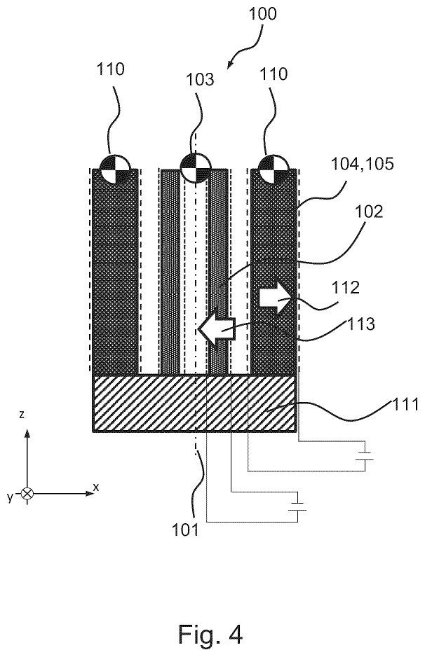

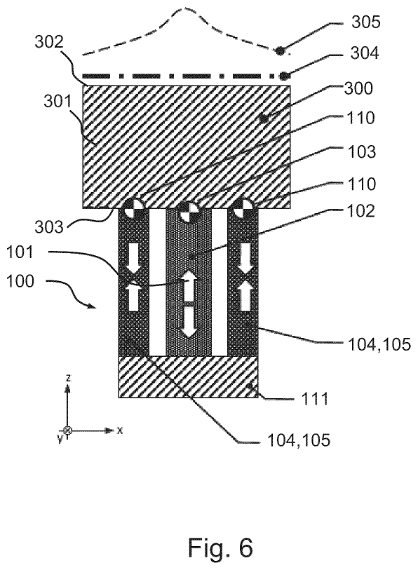

FIG. 4 shows a further exemplary embodiment of the actuator 100 according to the disclosure, wherein the compensation element 104 is formed as a further actuator element 105. In this case, the further actuator element 105 can be embodied identically to the actuator element 102, that is to say that if the actuator element 102 is formed as a piezoactuator element, then the further actuator element 105 is also formed as a piezoactuator element. The arrows 112, 113 in FIG. 4 here show in each case the imposition of the electric field. If the further actuator element 105, such as by virtue of the control thereof, is configured to compress, while the actuator element is configured to expand, as illustrated schematically by the arrows in FIG. 6, the total travel of the actuator 100 can be increased.

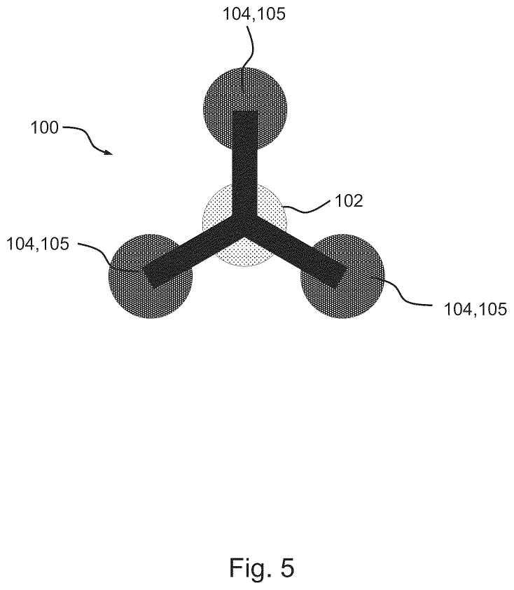

FIG. 5 shows a further exemplary embodiment of the actuator 100 according to the disclosure comprising a plurality of compensation elements 104 arranged around the actuator element 102 at the outer periphery, wherein the compensation elements 104 in the present case are formed as further actuator elements 105. If there is a functional failure of one of the compensation elements 104, then the remaining compensation elements 104/further actuator elements 105 can compensate for a temperature-induced change in length of the actuator element 102.

FIG. 6 shows the linking of the actuator 100 to an optical element 300, for example to a mirror or to a lens element. In this case, the compensation element 104 is formed as a further actuator element 105. In this case, the arrows in FIG. 6 indicate that the actuator element 102 is configured to expand, while the further actuator element 105 is configured to compress along or parallel to the adjustment axis 101. This results in a doubling of the total travel. The adjustment of the actuator 100 results in a bending moment being introduced in the mirror, which results in a deformation, at least in portions, of the mirror substrate 301 and thus of the optical surface, that is to say the reflective surface 302. In this case, the reference sign 304 represents the reflective surface in a non-deformed state, while the reference sign 305 indicates a deformation profile after the adjustment of the actuator 100.

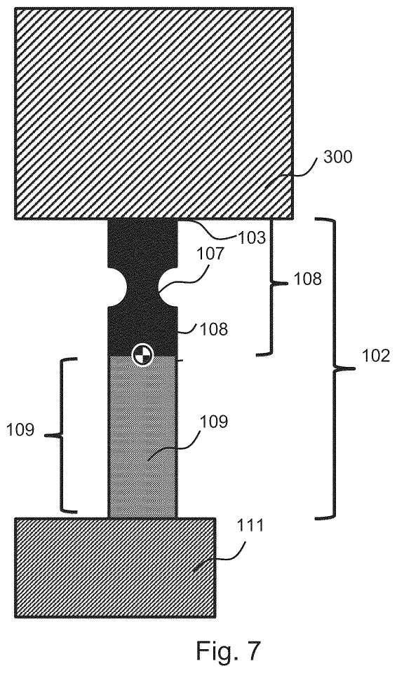

FIG. 7 shows the actuator element 102 in an enlarged illustration, in regard to the linking to the optical element 300. In this case, the actuator element 102 can be formed in bipartite fashion, only one part 109 of which is formed from an actively controlled material, such as from an electrostrictive, piezostrictive, magnetostrictive or photostrictive material. The other part 108, the adapter, additionally can have a constriction 107, thereby increasing the thermal resistance between the optical element 300 and the actuator element 102. In addition, the constriction 107 also serves for the mechanical decoupling of possibly unwanted moments. The compensation element 104 can be formed in bipartite fashion analogously to the actuator element 102.

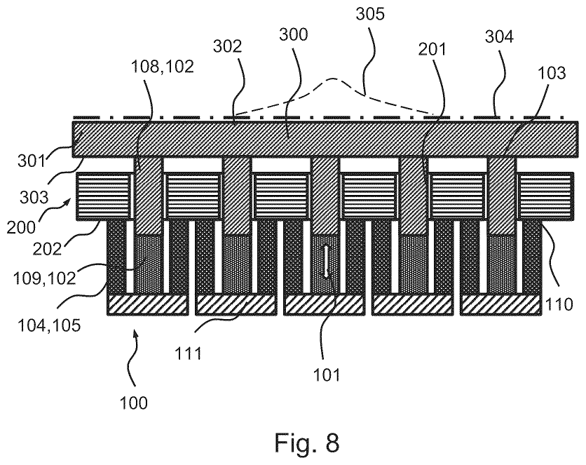

FIG. 8 shows a first exemplary embodiment of the deformation mirror 300 comprising a mirror substrate 301 having a reflective surface 302 and a mirror rear side 303 situated opposite the reflective surface. In the present case, a plurality of actuators 100 are connected to the mirror rear side 303 via the connection sites 103. If the actuator element 102 is formed in bipartite fashion, as in the present case, then the actuator element 102 is connected to the mirror rear side 303 via the other part 108, i.e. via the adapter 108. Alternatively, the other part 108 can also be a constituent part of the deformation mirror 300. The other part 108 can be formed from the same substance as the mirror 300. The other part 108 can be joined to the mirror substrate 301 or the mirror rear side 303, but can be monolithically connected to the mirror substrate 301 or ground from a glass block. The adjustment of the actuator element 102 relative to the compensation element 104 along or parallel to the adjustment axis 101 results in a bending moment being introduced in the mirror substrate 301, which results in a deformation, at least in portions, of the mirror 300, as illustrated schematically by the deformation profile 305.

The deformation mirror 300 according to FIG. 8 has a force frame, i.e. a frame 200 is arranged between the actuators 100 and the mirror rear side 303. The compensation element 104, at the coupling sites 110, is connected to a frame rear side 202 facing away from the mirror rear side 303, such that the coupling site 110 is held stationary with respect to the frame 200. The frame 200 or the mirror body 301 have bearing sites (not shown more specifically) for the mounting of the deformation mirror 300. However, the compensation element 104 can also be formed in bipartite fashion analogously to the actuator element 102, such that the other part/adapter 108 is connected to the frame rear side 202. The frame 200 additionally has a number of passages 201 adapted to the number of actuator elements 102, in which the actuator element 102, in the present case the other part 108/adapter of the actuator element 102, is arranged in movable fashion. FIG. 8 additionally illustrates that the extent of the actuator element 102, i.e. of the afore the one part 109 of the actuator element, is different from the extent of the compensation element 104 along or parallel to the adjustment axis 101.

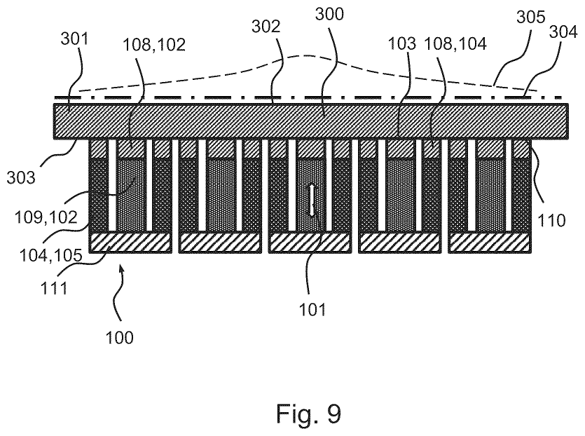

By contrast, the deformation mirror 300 according to FIG. 9 is embodied in force-frame-free fashion, that is to say that the compensation elements 104, at the coupling sites 110, are also connected to the mirror rear side 303, such that the coupling site 110 is held stationary with respect to the mirror, such as stationary with respect to the mirror rear side 303 or stationary with respect to a linking site which is embodied at the mirror rear side 303 and at which the coupling site 110 is connected to the mirror rear side 303. The mirror body 301 has bearing sites (not shown more specifically) for the mounting of the deformation mirror 300. In the present case, the actuator element 102 and the compensation element 104 are both formed in bipartite fashion, such that the other part/adapter 108 is connected to the mirror rear side 303. This simplifies the manufacture of the deformation mirror 300 and additionally makes it possible for the actuator element 102 and the compensation element 104 to be linked to the same heat source, namely the mirror rear side 303, such that an increase in the mirror temperature has the same effect on the compensation element 104 and the actuator element 102.

### LIST OF REFERENCE SIGNS

100 Actuator
101 Adjustment axis
102 Actuator element
103 Connection site
104 Compensation element
105 Further actuator element
106 Gap
107 Constriction
108 Adapter/other part
109 First part of actuator element
110 Coupling site
111 Connection mechanism
112 Direction of electric field of further actuator element
113 Direction of electric field of actuator element
200 Frame
201 Passage
202 Frame rear side
300 Mirror
301 Mirror substrate
302 Reflective surface
303 Mirror rear side
304 Profile of optical surface undeformed
305 Deformation profile
600 Projection exposure apparatus
601 Plasma light source
602 Collector mirror
603 Field facet mirror
604 Pupil facet mirror
605 First telescope mirror
606 Second telescope mirror
607 Deflection mirror
620 Mask stage
621 Mask
651 Mirror (projection lens)
652 Mirror (projection lens)
653 Mirror (projection lens)
654 Mirror (projection lens)
655 Mirror (projection lens)
656 Mirror (projection lens)
660 Wafer stage
661 Coated substrate
700 DUV lithography apparatus
701 DUV light source
702 DUV radiation/beam path
703 Beam shaping and illumination system (DUV)
704 Photomask
705 Projection system
706 Wafer
707 Lens element
708 Mirror
709 Optical axis

What is claimed is:

1. An actuator, comprising:
an actuator element having a first coefficient of thermal expansion, a first end and a connection site at its first end, the connection site configured to actively adjust an optical element along an adjustment axis;
a compensation element having a second coefficient of thermal expansion and a coupling site, a sign of the second coefficient of thermal expansion corresponding to a sign of the first coefficient of thermal expansion, the compensation element oriented coaxially relative to the adjustment axis, the coupling site configured to be connected to the optical element, the coupling site held stationary in space or stationary with respect to the optical element; and
a connection element connecting the actuator element and the compensation element at positions located remote from the connection site and from the coupling site.

2. The actuator of claim 1, wherein the connects element connects an end of the compensation element and an end of the actuator element.

3. The actuator of claim 1, wherein the first coefficient of thermal expansion is positive, and the second coefficient of thermal expansion is both positive.

4. The actuator of claim 1, wherein the first coefficient of thermal expansion matches the second coefficient of thermal expansion.

5. The actuator of claim 1, wherein an extent of the actuator element along the adjustment axis matches an extent of the compensation element along the adjustment axis.

6. The actuator of claim 1, wherein the compensation element is configured to actively adjust the optical element along the adjustment axis.

7. The actuator of claim 6, wherein the actuator element and the compensation element are bidirectionally adjustable along the adjustment axis or are monodirectionally adjustable along the adjustment axis.

8. The actuator of claim 6, wherein:
a first element selected from the group consisting of the actuator element and the compensation element is configured to compress along the adjustment axis;
a second element selected from the group consisting of the actuator element and the compensation element is configured to expand along the adjustment axis; and
the first element is different from the second element.

9. The actuator of claim 1, wherein the actuator element and the compensation element are connected to one another portions in a gap between them.

10. The actuator of claim 9, wherein the gap is at least partly filled with a liquid having a higher thermal conductivity than a thermal conductivity of air.

11. The actuator of claim 1, wherein the actuator element comprises first and second parts, and only the first part of the actuator element comprises electrostrictive, piezoelectric and/or magnetostrictive elements.

12. The actuator of claim 11, wherein the second part of the actuator element comprises a constriction.

13. The actuator of claim 11, wherein a heat transfer resistance of the second part of the actuator element is greater than a heat transfer resistance of the first part of the actuator element.

14. The actuator of claim 1, wherein:
a first element selected from the group consisting of the actuator element and the compensation element is a hollow body;
a second element elected from the group consisting of the actuator element and the compensation element is disposed in the hollow body; and
the first element is different from the second element.

15. The actuator of claim 1, comprising a plurality of compensation elements connected to the actuator element.

16. A system, comprising:
an optical element; and
an actuator, comprising:
an actuator element having a first coefficient of thermal expansion, a first end and a connection site at its first end, the connection site configured to actively adjust the optical element along an adjustment axis;
a compensation element having a second coefficient of thermal expansion and a coupling site, a sign of the second coefficient of thermal expansion corresponding to a sign of the first coefficient of thermal expansion, the compensation element oriented coaxially relative to the adjustment axis, the coupling site connected to the optical element, the coupling site held stationary in space or stationary with respect to the optical element; and
a connection element connecting the actuator element and the compensation element at positions located remote from the connection site and from the coupling site.

17. The system of claim 16, wherein:
the system is a microlithographic projection exposure apparatus comprising an illumination system and a projection system,
wherein the optical element is in the illumination system or the projection system.

18. A deformation mirror, comprising:
a mirror substrate comprising a reflective surface and a mirror rear side opposite the reflective surface; and
an actuator, comprising:
an actuator element having a first coefficient of thermal expansion, a first end and a connection site at its first end, the connection site configured to actively adjust the reflective surface along an adjustment axis;
a compensation element having a second coefficient of thermal expansion and a coupling site, a sign of the second coefficient of thermal expansion corresponding to a sign of the first coefficient of thermal expansion, the compensation element oriented coaxially relative to the adjustment axis, the coupling site connected to the mirror substrate, the coupling site held stationary in space or stationary with respect to the optical element; and
a connection element connecting the actuator element and the compensation element at positions located remote from the connection site and from the coupling site.

19. The deformation mirror of claim 18, further comprising a frame between the actuator and the mirror rear side so that at the coupling site the compensation element is connected to a frame rear side facing away from the mirror rear side, wherein the frame comprises a passage in which the actuator element is movably disposed.

20. The deformation mirror of claim 18, wherein, at the coupling site, the compensation element is directly or indirectly connected to the mirror rear side.
